(19) United States
(12) Patent Application Publication
(10) Pub. No.: US 2015/0325725 A1
(43) Pub. Date: Nov. 12, 2015

(54) GLASS SUBSTRATE FOR SOLAR CELL

(71) Applicant: Nippon Electric Glass Co., Ltd., Shiga (JP)

(72) Inventors: Masato MUGURUMA, Shiga (JP); Hironori TAKASE, Shiga (JP); Takashi MURATA, Shiga (JP); Junichi ISEKI, Shiga (JP)

(21) Appl. No.: 14/367,302

(22) PCT Filed: Dec. 21, 2012
(86) PCT No.: PCT/JP2012/083217

§ 371 Date: Jun. 20, 2014

(30) Foreign Application Priority Data
Dec. 22, 2011 (JP) 2011-281035

(51) Int. Cl. H01L 31/0392; H01L 51/00

(52) U.S. Cl. CPC H01L 31/0392; H01L 51/0096

(57) ABSTRACT

Provided is a glass substrate for a solar cell, including as a glass composition, in terms of mass %, 40 to 70% of SiO₂, 1 to 20% of Al₂O₃, and 1 to 20% of Na₂O, and having a water content in glass of less than 25 mmol/L.

### TECHNICAL FIELD

The present invention relates to a glass substrate for a solar cell, in particular, a glass substrate for a solar cell suitable for a thin-film solar cell such as a CIGS-based solar cell or a CdTe-based solar cell.

### BACKGROUND ART

In a chalcopyrite-type thin-film solar cell, for example, a CIGS-based solar cell, Cu(In,Ga)Se₂, which is a chalcopyrite-type compound semiconductor comprising Cu, In, Ga, and Se, is formed as a photoelectric conversion film on a glass substrate. In addition, the photoelectric conversion film is formed using a multi-source evaporation method, a selenization method, or the like.

In order to form the photoelectric conversion film from Cu, In, Ga, Se, and the like using the multi-source deposition method, the selenization method, or the like, a heat treatment step at about 500 to 600° C. is required.

In a CdTe-based solar cell as well, a photoelectric conversion film comprising Cd and Te is formed on a glass substrate. In this case, a heat treatment step at about 500° C. to 600° C. is also required.

Further, a production process for a dye-sensitized solar cell includes the step of forming a transparent conductive film, a TiO₂ porous body, on a glass substrate, and heat treatment at high temperature (for example, 500° C. or more) is necessary to form a transparent conductive film having high quality or the like on the glass substrate.

### CITATION LIST

Patent Literature 1: JP 11-135819 A

Patent Literature 2: JP 2005-89286 A

Patent Literature 3: JP 2987523 B2

### SUMMARY OF INVENTION

### Technical Problem

Soda-lime glass has been heretofore used as a glass substrate in a CIGS-based solar cell, a CdTe-based solar cell, and the like. However, soda-lime glass is liable to have thermal deformation and thermal shrinkage in a heat treatment step at high temperature. In order to solve the problem, the use of high strain point glass as a glass substrate for a solar cell has been currently studied (see Patent Literature 1).

However, the high strain point glass disclosed in Patent Literature 1 did not have a sufficiently high strain point, and hence, when the film formation temperature of a photoelectric conversion film or the like was more than 600 to 650° C., the high strain point glass was liable to have thermal deformation and thermal shrinkage, with the result that the photoelectric conversion efficiency thereof was not able to be enhanced sufficiently. Note that in a CIGS-based solar cell or a CdTe-based solar cell, the formation of a photoelectric conversion film at high temperature improves the crystal quality of the photoelectric conversion film, leading to the enhancement of the photoelectric conversion efficiency.

Further, the glass substrate disclosed in Patent Literature 2 has a strain point of more than 600 to 650° C. However, this glass substrate has too low a thermal expansion coefficient, and hence the thermal expansion coefficient does not match those of an electrode film and photoelectric conversion film in a thin-film solar cell, that of a TiO₂ porous body in a dye-sensitized solar cell, and that of a sealing frit. As a result, a defect such as film peeling is liable to be caused.

Besides, the glass substrate disclosed in Patent Literature 3 has a strain point of more than 650° C. However, this glass substrate comprises an alkali component, in particular, Na₂O to a small extent, and hence supplying Na to a photoelectric conversion film is difficult and a photoelectric conversion film having high quality cannot be formed, with the result that the photoelectric conversion efficiency cannot be enhanced unless an alkali supply film is formed separately. On the other hand, when the content of an alkali component, in particular, Na₂O is increased, the strain point is liable to lower. Note that, when an alkali component, in particular, Na₂O diffuses from the glass substrate in a CIGS-based solar cell, a chalcopyrite crystal easily precipitates.

Thus, a technical object of the present invention is to invent a glass substrate for a solar cell, the glass substrate comprising an alkali component, in particular, Na₂O, having a sufficiently high strain point, and having a thermal expansion coefficient that can match those of peripheral members.

### Solution to Problem

The inventors of the present invention have made intensive studies and have consequently found that the above-mentioned technical object can be achieved by controlling the content of each component of glass and controlling the water content in the glass. Thus, the finding is proposed as the present invention. That is, a glass substrate for a solar cell of the present invention comprises as a glass composition, in terms of mass %, 40 to 70% of SiO₂, 1 to 20% of Al₂O₃, and 1 to 20% of Na₂O, and has a water content in glass of less than 25 mmol/L.

Herein, the term “water content in glass” refers to a value calculated by using the following method on the basis of light absorption at a wavelength of 2,700 nm.

First, light absorption at wavelengths of 2,500 to 6,500 nm is measured with a general-purpose FT-IR apparatus to determine an absorption maximum value Aₘ [%] in the vicinity of the wavelength of 2,700 nm. Next, an absorption coefficient α [cm⁻¹] is calculated on the basis of Mathematical Equation 1 described below. Note that in Mathematical Equation 1, d [cm] represents the thickness of a measurement sample and Tᵢ [%] represents the internal transmittance of the measurement sample.

α=(1/d)×log₁₀{1/(Tᵢ/100)} [cm⁻¹] (1)

Herein, the internal transmittance Tᵢ is a value calculated from the absorption maximum value Aₘ and a refractive index n_{d} by using Mathematical Equation 2 described below.

Tᵢ=Aₘ/{(1−R)} (2)

where R=[1−{(n_{d}−1)/(n_{d}+1)}²]².

Subsequently, a water content c [mol/L] is calculated on the basis of Mathematical Equation 3 described below.

c=α/e (3)

Note that e can be read from page 350 of “Glastechnischen Berichten” Vol. 36, No. 9. Further, in the present application, 110 [L mol⁻¹ cm⁻¹] is adopted as e.

The glass substrate for a solar cell of the present invention comprises 1 to 20 mass % of Na₂O. As a result, supplying Na to a photoelectric conversion film is possible, and hence the photoelectric conversion efficiency thereof can be enhanced without forming an alkali supply film separately. In addition, the melting temperature and forming temperature of the glass substrate lower and the thermal expansion coefficient thereof is likely to match those of peripheral members.

The glass substrate for a solar cell of the present invention has a water content in glass of less than 25 mmol/L. As a result, the strain point can be increased, resulting in being able to increase the content of an alkali component, in particular, Na₂O, and hence both the high strain point and the quality of the photoelectric conversion film can be achieved at high levels.

Second, the glass substrate for a solar cell of the present invention preferably comprises as a glass composition, in terms of mass %, 40 to 70% of SiO₂, 3 to 20% of Al₂O₃, 0 to 15% of B₂O₃, 0 to 10% of Li₂O, 1 to 20% of Na₂O, 0 to 15% of K₂O, 5 to 35% of MgO+CaO+SrO+BaO, and 0 to 10% of ZrO₂, and has a water content in glass of less than 25 mmol/L. Herein, the term “MgO+CaO+SrO+BaO” refers to the total amount of MgO, CaO, SrO, and BaO.

Third, the glass substrate for a solar cell of the present invention preferably has a strain point of 560° C. or more. With this, a photoelectric conversion film can be easily formed at high temperature, the crystal quality of the photoelectric conversion film is improved, and the glass substrate is difficult to have thermal deformation and thermal shrinkage. Consequently, the photoelectric conversion efficiency can be enhanced sufficiently while the production cost of a thin-film solar cell or the like is reduced. Herein, the “strain point” refers to a value measured on the basis of ASTM C336-71.

Fourth, the glass substrate for a solar cell of the present invention preferably has a thermal expansion coefficient at 30 to 380° C. of 70×10⁻⁷ to 100×10⁻⁷/° C. Herein, the “thermal expansion coefficient at 30 to 380° C.” refers to an average value measured with a dilatometer.

Fifth, the glass substrate for a solar cell of the present invention is preferably used in a thin-film solar cell.

Sixth, the glass substrate for a solar cell of the present invention is preferably used in a dye-sensitized solar cell.

### DESCRIPTION OF EMBODIMENTS

A glass substrate for a solar cell according to an embodiment of the present invention comprises as a glass composition, in terms of mass %, 40 to 70% of SiO₂, 1 to 20% of Al₂O₃, and 1 to 20% of Na₂O. The reasons why the content of each component is limited as mentioned above are described below.

SiO₂ is a component that forms a network of glass. The content of SiO₂ is 40 to 70%, preferably 45 to 60%, more preferably 47 to 57%, still more preferably 49 to 52%. When the content of SiO₂ is too large, the viscosity at high temperature improperly increases, the meltability and formability are liable to lower, and the thermal expansion coefficient lowers excessively, with the result that it is difficult to match the thermal expansion coefficient to those of an electrode film and photoelectric conversion film in a thin-film solar cell or the like. On the other hand, when the content of SiO₂ is too small, the denitrification resistance is liable to deteriorate. In addition, the thermal expansion coefficient increases excessively, and the thermal shock resistance of the glass substrate is liable to lower, with the result that the glass substrate is liable to have a crack in a heat treatment step at the time of producing a thin-film solar cell or the like.

Al₂O₃ is a component that increases the strain point, a component that enhances the climate resistance and chemical durability, and a component that increases the surface hardness of the glass substrate. The content of Al₂O₃ is 1 to 20%, preferably 5 to 17%, more preferably 8 to 16%, still more preferably more than 10.0 to 15%, particularly preferably more than 11.0 to 14.5%, most preferably 11.5 to 14%. When the content of Al₂O₃ is too large, the viscosity at high temperature improperly increases, and the meltability and formability are liable to lower. On the other hand, when the content of Al₂O₃ is too small, the strain point is liable to lower. Note that, when a glass substrate has a high surface hardness, the glass substrate is hardly damaged in the step of removing a photoelectric conversion film at the time of performing patterning for a CIGS-based solar cell.

Na₂O is a component that adjusts the thermal expansion coefficient and a component that reduces the viscosity at high temperature to increase the meltability and formability. Further, Na₂O is a component that is effective for the growth of a chalcopyrite crystal in the manufacture of a CIGS-based solar cell and a component that is important for enhancing the photoelectric conversion efficiency. The content of Na₂O is 1 to 20%, preferably 2 to 15%, more preferably 3.5 to 13%, still more preferably more than 4.3 to 10%. When the content of Na₂O is too large, the strain point is liable to lower, the thermal expansion coefficient increases excessively, and the thermal shock resistance of the glass substrate is liable to lower. As a result, the glass substrate is liable to have thermal shrinkage and thermal deformation, and to have a crack in a heat treatment step at the time of producing a thin-film solar cell or the like. On the other hand, when the content of Na₂O is too small, the above-mentioned effects are hardly obtained.

In addition to the above-mentioned components, for example, the following components may be added.

B₂O₃ is a component that reduces the viscosity of glass, thereby lowering the melting temperature and forming temperature, but is a component that lowers the strain point and a component that causes a furnace refractory material to wear with the volatilization of components at the time of melting. Further, B₂O₃ is a component that increases the water content in the glass. Thus, the content of B₂O₃ is preferably 0 to less than 15%, 0 to less than 5%, 0 to 1.5%, particularly preferably 0 to less than 0.1%.

Li₂O is a component that adjusts the thermal expansion coefficient and a component that reduces the viscosity at high temperature to increase the meltability and formability. Further, Li₂O is a component that is effective for the growth of a chalcopyrite crystal in the manufacture of a CIGS-based solar cell as in Na₂O. However, Li₂O is a component whose material cost is high and which significantly lowers the strain point. Thus, the content of Li₂O is preferably 0 to 10%, 0 to 2%, particularly preferably 0 to less than 0.1%.

K₂O is a component that adjusts the thermal expansion coefficient and a component that reduces the viscosity at high temperature to increase the meltability and formability. Further, K₂O is a component that is effective for the growth of a chalcopyrite crystal in the manufacture of a CIGS-based solar cell and a component that is important for enhancing the photoelectric conversion efficiency as in Na₂O. However, when the content of K₂O is too large, the strain point is liable to lower, the thermal expansion coefficient increases excessively, and the thermal shock resistance of the glass substrate is liable to lower. As a result, the glass substrate is liable to have thermal shrinkage and thermal deformation, and to have a crack in a heat treatment step at the time of producing a thin-film solar cell or the like. Thus, the content of K₂O is preferably 0 to 15%, 0.1 to 10%, particularly preferably 4 to 8%.

MgO+CaO+SrO+BaO are components that reduce the viscosity at high temperature to increase the meltability and formability. However, when the content of MgO+CaO+SrO+BaO is too large, the denitrification resistance is liable to deteriorate and a glass substrate is difficult to be formed. Thus, the content of MgO+CaO+SrO+BaO is preferably 5 to 35%, 10 to 30%, 15 to 27%, 18 to 25%, particularly preferably 20 to 23%.

MgO is a component that reduces the viscosity at high temperature to increase the meltability and formability. Further, MgO is a component that has a great effect of preventing a glass substrate from breaking easily among alkaline earth metal oxides. However, MgO is a component that is liable to cause devitrified crystals to precipitate. Thus, the content of MgO is preferably 0 to 10%, 0 to less than 5%, 0.01 to 4%, 0.03 to 3%, particularly preferably 0.5 to 2.5%.

CaO is a component that reduces the viscosity at high temperature to increase the meltability and formability. However, when the content of CaO is too large, the denitrification resistance is liable to deteriorate and a glass substrate is difficult to be formed. Thus, the content of CaO is preferably 0 to 10%, 0.1 to 9%, more than 2.9 to 8%, 3.0 to 7.5%, particularly preferably 4.2 to 6%.

SrO is a component that reduces the viscosity at high temperature to increase the meltability and formability. Further, SrO is a component that suppresses the precipitation of devitrified crystals of the ZrO₂ system when SrO coexists with ZrO₂. When the content of SrO is too large, devitrified crystals of the feldspar group are liable to precipitate and the material cost significantly increases. Thus, the content of SrO is preferably 0 to 15%, 0.1 to 13%, particularly preferably more than 4.0 to 12%.

BaO is a component that reduces the viscosity at high temperature to increase the meltability and formability. When the content of BaO is too large, devitrified crystals of the barium feldspar group are liable to precipitate and the material cost significantly increases. In addition, the density increases and the cost of a supporting member is liable to increase significantly. On the other hand, when the content of BaO is too small, the viscosity at high temperature improperly increases, and the meltability and formability tend to lower. Thus, the content of BaO is preferably 0 to 15%, 0.1 to 12%, particularly preferably more than 2.0 to 10%.

ZrO₂ is a component that increases the strain point without increasing the viscosity at high temperature. However, when the content of ZrO₂ is too large, the density is liable to increase and the glass substrate is liable to break. Besides, devitrified crystals of the ZrO₂ system are liable to precipitate and a glass substrate is difficult to be formed. Thus, the content of ZrO₂ is preferably 0 to 15%, 0 to 10%, 0 to 7%, 0.1 to 6.5%, particularly preferably 2 to 6%.

Fe is present in the state of Fe²⁺ or Fe³⁺ in glass, and Fe²⁺ has particularly strong light absorption properties in the near-infrared region. Thus, Fe²⁺ is likely to absorb radiation energy in a glass melting furnace with a large capacity and has the effect of enhancing melting efficiency. Further, Fe³⁺ releases oxygen when the valence of iron changes, thus having a fining effect. Besides, the production cost of a glass substrate can be reduced when the use of a high-purity material (material having an extremely low content of Fe₂O₃) is restricted and a material containing Fe₂O₃ at a small ratio is used. On the other hand, when the content of Fe₂O₃ is too large, glass is liable to absorb solar light, and hence the surface temperature of the resultant thin-film solar cell or the like easily rises, with the result that the photoelectric conversion efficiency thereof may deteriorate. Further, radiation energy in the furnace is absorbed near the energy source and does not reach the central portion of the furnace, with the result that the thermal distribution in the glass melting furnace is liable to be uneven. Thus, the content of Fe₂O₃ is preferably 0 to 1%, particularly preferably 0.01 to 1%. Further, the lower limit range of Fe₂O₃ is suitably more than 0.020%, more than 0.050%, particularly suitably more than 0.080%. Note that, in the present invention, regardless of the valence of Fe, the content of iron oxide is expressed on the basis of a value obtained by conversion to “Fe₂O₃.”

TiO₂ is a component that prevents coloring by ultraviolet light and enhances the climate resistance. However, when the content of TiO₂ is too large, glass is liable to denitrify and the glass itself is liable to be colored into a brownish-red color. Thus, the content of TiO₂ is preferably 0 to 10%, particularly preferably 0 to less than 0.1%.

P₂O₅ is a component that enhances the denitrification resistance, a component that particularly suppresses the precipitation of devitrified crystals of the ZrO₂ system, and a component that prevents a glass substrate from easily breaking. However, when the content of P₂O₅ is too large, glass is liable to have phase separation in an opaque white color. Thus, the content of P₂O₅ is preferably 0 to 10%, 0 to 0.2%, particularly preferably 0 to less than 0.1%.

ZnO is a component that reduces the viscosity at high temperature. When the content of ZnO is too large, the denitrification resistance is liable to deteriorate. Thus, the content of ZnO is preferably 0 to 10%, particularly preferably 0 to 5%.

SO₃ is a component that reduces the water content in glass and a component that acts as a fining agent. The content of SO₃ is preferably 0 to 1%, 0.001 to 1%, particularly preferably 0.01 to 0.5%. Note that, when glass substrates are formed by a float method, the glass substrates can be produced in a large quantity at low cost, but in this case, it is preferred to use sodium sulfate decahydrate as a fining agent.

Cl is a component that reduces the water content in glass and a component that acts as a fining agent. The content of Cl is preferably 0 to 1%, 0.001 to 1%, particularly preferably 0.01 to 0.5%.

As₂O₃ is a component that acts as a fining agent, but is a component that colors glass when a glass substrate is formed by a float method and a component that may give a load to the environment. Thus, the content of As₂O₃ is preferably 0 to 1%, particularly preferably 0 to less than 0.1%.

Sb₂O₃ is a component that acts as a fining agent, but is a component that colors glass when a glass substrate is formed by a float method and a component that may give a load to the environment. Thus, the content of Sb₂O₃ is preferably 0 to 1%, particularly preferably 0 to less than 0.1%.

SnO₂ is a component that acts as a fining agent but a component that deteriorates the denitrification resistance. Thus, the content of SnO₂ is preferably 0 to 1%, particularly preferably 0 to less than 0.1%.

In addition to the above-mentioned components, each of F and CeO₂ may be added up to 1% in order to enhance the meltability, fining property, and formability. Moreover, each of Nb₂O₅, HfO₂, Ta₂O₅, Y₂O₃, and La₂O₃ may be added up to 3% in order to enhance the chemical durability. Further, rare-earth oxides and transition metal oxides except the above-mentioned oxides may be added up to 2% in total in order to adjust the color tone.

In the glass substrate for a solar cell according to this embodiment, the water content in glass is less than 25 mmol/L, preferably 10 to 23 mmol/L, 15 to 21 mmol/L, particularly preferably 18 to 20 mmol/L. With this, the high strain point thereof can be maintained even if an alkali component, in particular, Na₂O, which is effective for improving the photoelectric conversion efficiency, is added to a large extent.

When the water content in glass is too large, the strain point improperly lowers. On the other hand, when the water content in glass is too small, the production cost of the glass substrate increases because it is difficult to adopt a combustion method, by which a large amount of glass can be melted at low cost.

The following methods are given as methods of reducing the water content in glass. (1) Materials having a low water content are selected, (2) components (such as Cl and SO₃) decreasing the water content in glass are added, (3) the water content in the atmosphere in a furnace is reduced, (4) N₂ bubbling is carried out in molten glass, (5) a small melting furnace is adopted, (6) the flow rate of molten glass is increased, and (7) an electric melting method is adopted.

Note that aluminum hydroxide is generally used as an introduction material for Al₂O₃ in order to enhance the meltability. Thus, when a related-art glass substrate for a solar cell comprised 5% or more of Al₂O₃, in particular, 8% or more in its glass composition, aluminum hydroxide was comprised at a large ratio in a material batch, with the result that the glass substrate had a water content in glass of 25 mmol/L or more.

The glass substrate for a solar cell according to this embodiment has a thermal expansion coefficient at 30 to 380° C. of preferably 70×10⁻⁷ to 100×10⁻⁷/° C., particularly preferably 80×10⁻⁷ to 90×10⁻⁷/° C. With this, the thermal expansion coefficient easily matches those of an electrode film and photoelectric conversion film in a thin-film solar cell. Note that, when the thermal expansion coefficient is too high, the thermal shock resistance of the glass substrate is liable to lower, with the result that the glass substrate is liable to have a crack in a heat treatment step at the time of producing a thin-film solar cell.

The glass substrate for a solar cell according to this embodiment has a density of preferably 2.90 g/cm³ or less, particularly preferably 2.85 g/cm³ or less. With this, the mass of the glass substrate is reduced, and hence the cost of a supporting member in a thin-film solar cell can be easily reduced. Note that the “density” can be measured by a well-known Archimedes method.

The glass substrate for a solar cell according to this embodiment has a strain point of preferably 560° C. or more, more than 600 to 650° C., more than 605 to 640° C., particularly preferably more than 610 to 630° C. With this, the glass substrate is difficult to have thermal shrinkage and thermal deformation in a heat treatment step at the time of producing a thin-film solar cell. Note that the upper limit of the strain point is not particularly set, but when the strain point is too high, the melting temperature and the forming temperature may rise improperly.

The glass substrate for a solar cell according to this embodiment has a temperature at 10^{4.0} dPa·s of preferably 1,200° C. or less, particularly preferably 1,180° C. or less. With this, the glass substrate is easily formed at low temperature. Note that the “temperature at 10^{4.0} dPa·s” can be measured by a platinum sphere pull up method.

The glass substrate for a solar cell according to this embodiment has a temperature at 10^{2.5} dPa·s of preferably 1,520° C. or less, particularly preferably 1,460° C. or less. With this, a glass material thereof is easily melted at low temperature. Note that the “temperature at 10^{2.5} dPa·s” can be measured by a platinum sphere pull up method.

The glass substrate for a solar cell according to this embodiment has a liquidus temperature of preferably 1,160° C. or less, particularly preferably 1,100° C. or less. When the liquidus temperature is too high, the glass is liable to devitrify at the time of the forming thereof and the formability is liable to lower. Herein, the term “the liquidus temperature” refers to a value obtained by measuring a maximum temperature at which crystals of glass are deposited after glass powder that passed through a standard 30-mesh sieve (500 μm) and remained on a 50-mesh sieve (300 μm) is placed in a platinum boat and then the platinum boat is kept for 24 hours in a gradient heating furnace.

The glass substrate for a solar cell according to this embodiment has a liquidus viscosity of preferably 10^{4.0} dPa·s or more, particularly preferably 10^{4.3} dPa·s or more. When the liquidus viscosity is too low, the glass is liable to devitrify at the time of the forming thereof and the formability is liable to lower. Herein, the term “liquidus viscosity” refers to a value obtained through measurement of a viscosity of glass at the liquidus temperature by a platinum sphere pull up method.

The glass substrate for a solar cell according to this embodiment can be manufactured by loading a glass material, which is prepared so as to have a glass composition in the above-mentioned glass composition range and the above-mentioned water content, into a continuous melting furnace, heating and melting the glass material, then removing bubbles from the resultant glass melt, feeding the glass melt into a forming apparatus, and forming the glass melt into a sheet shape, followed by annealing.

It is possible to exemplify, as a method of forming a glass substrate, a float method, a slot down-draw method, an overflow down-draw method, and a redraw method. In particular, when inexpensive glass substrates are produced in a large quantity, a float method is preferably adopted.

The glass substrate for a solar cell according to this embodiment preferably does not undergo chemical tempering treatment, in particular, ion exchange treatment. As described above, a heat treatment step at high temperature is carried out to produce a thin-film solar cell or the like. In the heat treatment step at high temperature, a tempered layer (compression stress layer) disappears, and hence performing chemical tempering treatment only provides a few benefits. Further, because of the same reason as above, physical tempering treatment such as air cooling tempering preferably is not performed as well.

Particularly when a CIGS-based solar cell is produced, ion exchange treatment applied to a glass substrate decreases the number of Na ions in the glass surface, and hence the photoelectric conversion efficiency is liable to deteriorate. In this case, it is necessary to form separately an alkali supply film.

The glass substrate for a solar cell according to this embodiment preferably has a photoelectric conversion film having a thermal expansion coefficient of 50×10⁻⁷ to 120×10⁻⁷/° C. and formed at a film formation temperature of 500 to 700° C. With this, the crystal quality of the photoelectric conversion film is improved, and the photoelectric conversion efficiency of a thin-film solar cell or the like can be enhanced. In addition, the thermal expansion coefficient of the glass substrate and that of the photoelectric conversion film are likely to be matched to each other.

### Examples

Examples of the present invention are described in detail below. Note that the following examples are merely for illustrative purposes. The present invention is by no means limited to the following examples.

Table 1 and Table 2 show Examples of the present invention (Sample Nos. 1 to 16) and Comparative Examples (Sample No. 17).

TABLE 1

| | | Example | | | | | | | | |
|---|---|---|---|---|---|---|---|---|---|---|
| | | No. 1 | No. 2 | No. 3 | No. 4 | No. 5 | No. 6 | No. 7 | No. 8 | No. 9 |
| Glass | SiO₂ | 55.8 | 55.8 | 55.8 | 55.8 | 57.8 | 50 | 50 | 50 | 60 |
| composition | Al₂O₃ | 7 | 7 | 7 | 7 | 7 | 13.5 | 13.5 | 13.5 | 10.1 |
| (wt %) | MgO | 2 | 2 | 2 | 2 | 2 | — | — | — | 5 |
| | CaO | 2 | 2 | 2 | 2 | 5 | 7 | 7 | 7 | 6 |
| | SrO | 9 | 9 | 9 | 9 | 7 | 12.4 | 12.4 | 12.4 | 1.6 |
| | BaO | 8.5 | 8.5 | 8.5 | 8.5 | 8 | 2 | 2 | 2 | 0.1 |
| | Na₂O | 4.5 | 4.5 | 4.5 | 4.5 | 4 | 7 | 7 | 7 | 5 |
| | K₂O | 6.5 | 6.5 | 6.5 | 6.5 | 7 | 2.9 | 2.9 | 2.9 | 9.5 |
| | ZrO₂ | 4.5 | 4.5 | 4.5 | 4.5 | 2 | 5 | 5 | 5 | 2.5 |
| | Fe₂O₃ | 0.1 | 0.1 | 0.1 | 0.1 | 0.1 | 0.1 | 0.1 | 0.1 | 0.1 |
| | SO₃ | 0.1 | 0.1 | 0.1 | 0.1 | 0.1 | 0.1 | 0.1 | 0.1 | 0.1 |

| | | | | | | | | | |
|---|---|---|---|---|---|---|---|---|---|
| α (×10⁻⁷/° C.) | 85 | 85 | 85 | 85 | 85 | 82 | 82 | 82 | 86 |
| d (g/cm³) | 2.82 | 2.82 | 2.82 | 2.82 | 2.77 | 2.83 | 2.83 | 2.83 | 2.56 |
| H₂O (mmol/L) | 9.7 | 15.7 | 19.8 | 24.1 | 10 | 10.1 | 19.4 | 23.9 | 20.5 |
| Ps (° C.) | 586 | 583 | 580 | 575 | 577 | 629 | 621 | 619 | 590 |
| Ta (° C.) | 630 | 627 | 624 | 621 | 621 | 673 | 665 | 663 | 635 |
| Ts (° C.) | 840 | 837 | 834 | 829 | 830 | 860 | 852 | 850 | 850 |
| 10⁴ dPa · s (° C.) | 1,150 | 1,150 | 1,150 | 1,150 | 1,130 | 1,150 | 1,150 | 1,150 | 1,175 |
| 10³ dPa · s (° C.) | 1,310 | 1,310 | 1,310 | 1,310 | 1,300 | 1,290 | 1,290 | 1,290 | 1,340 |
| 10^{2.5} dPa · s (° C.) | 1,410 | 1,410 | 1,410 | 1,410 | 1,400 | 1,390 | 1,390 | 1,390 | 1,470 |
| 10² dPa · s (° C.) | 1,510 | 1,510 | 1,510 | 1,510 | 1,500 | 1,525 | 1,525 | 1,525 | — |
| TL (° C.) | 1,010 | 1,010 | 1,010 | 1,010 | 1,070 | 1,115 | 1,115 | 1,115 | 1,200 |
| log₁₀η_{TL} (dPa · s) | 5.3 | 5.3 | 5.3 | 5.3 | 4.6 | 4.3 | 4.3 | 4.3 | 4 |

TABLE 2

| | | | | | | | | | Comparative |
|---|---|---|---|---|---|---|---|---|---|
| | | Example | | | | | | | Example |
| | | No. 10 | No. 11 | No. 12 | No. 13 | No. 14 | No. 15 | No. 16 | No. 17 |
| Glass | SiO₂ | 51 | 51 | 51 | 61.3 | 65.3 | 55.8 | 55.8 | 57.8 |
| composition | Al₂O₃ | 13 | 13 | 13 | 9.5 | 5.5 | 18.5 | 17 | 7 |
| (wt %) | MgO | 1 | 1 | 1 | 7 | 8 | 4.5 | 5.5 | 2 |
| | CaO | 6.5 | 6.5 | 6.5 | 4.5 | 3 | 2.5 | 3 | 5 |
| | SrO | 9.1 | 9.1 | 9.1 | 1 | 0 | 1.5 | 1.5 | 7 |
| | BaO | 4.3 | 4.3 | 4.3 | 0.5 | 0 | 2.5 | 1 | 8 |
| | Na₂O | 5 | 5 | 5 | 5 | 3.5 | 9 | 7.5 | 4 |
| | K₂O | 5.3 | 5.3 | 5.3 | 7.5 | 10.5 | 3.5 | 6.5 | 7 |
| | ZrO₂ | 4.6 | 4.6 | 4.6 | 3.5 | 4 | 2 | 2 | 2 |
| | Fe₂O₃ | 0.1 | 0.1 | 0.1 | 0.1 | 0.1 | 0.1 | 0.1 | 0.1 |
| | SO₃ | 0.1 | 0.1 | 0.1 | 0.1 | 0.1 | 0.1 | 0.1 | 0.1 |

| | | | | | | | | |
|---|---|---|---|---|---|---|---|---|
| α (×10⁻⁷/° C.) | 81 | 81 | 81 | 76 | 76 | 79 | 85 | 85 |
| d (g/cm³) | 2.81 | 2.81 | 2.81 | 2.51 | 2.55 | 2.57 | 2.56 | 2.77 |
| H₂O (mmol/L) | 9.2 | 18.3 | 24.9 | 14.7 | 15.2 | 14.5 | 15.5 | 37.8 |
| Ps (° C.) | 631 | 624 | 619 | 610 | 605 | 615 | 605 | 558 |
| Ta (° C.) | 677 | 670 | 666 | 650 | 650 | 660 | 650 | 602 |
| Ts (° C.) | 875 | 868 | 864 | 870 | 865 | 890 | 880 | 811 |
| 10⁴ dPa · s (° C.) | 1,165 | 1,165 | 1,165 | 1,220 | 1,200 | 1,240 | 1,230 | 1,130 |
| 10³ dPa · s (° C.) | 1,315 | 1,315 | 1,315 | 1,400 | 1,365 | 1,410 | 1,400 | 1,300 |
| 10^{2.5} dPa · s (° C.) | 1,410 | 1,410 | 1,410 | 1,510 | 1,470 | 1,520 | 1,510 | 1,400 |
| 10² dPa · s (° C.) | 1,530 | 1,530 | 1,530 | 1,650 | 1,595 | 1,650 | 1,635 | 1,500 |
| TL (° C.) | 1,120 | 1,120 | 1,120 | 1,210 | 1,220 | 1,235 | 1,230 | 1,070 |
| log₁₀η_{TL} (dPa · s) | 4.4 | 4.4 | 4.4 | 4.1 | 3.9 | 4 | 4 | 4.6 |

Sample Nos. 1 to 17 were produced in the following manner. First, batches were blended so that each of the glass compositions in the tables was attained. The batches were loaded into a platinum crucible or an aluminum crucible and were then melted in an electric furnace or a gas furnace at 1,550° C. for 2 hours. The water content in glass was adjusted by selecting suitable kinds of materials and a suitable melting furnace. Next, the resultant molten glass was caused to flow on a carbon plate to be formed into a plate shape, followed by annealing. After that, predetermined processing was performed in accordance with each measurement.

Each of the resultant samples was evaluated for its thermal expansion coefficient α, density d, water content in glass, strain point Ps, annealing temperature Ta, softening temperature Ts, temperature at 10⁴ dPa·s, temperature at 10³ dPa·s, temperature at 10^{2.5} dPa·s, temperature at 10² dPa·s, liquidus temperature TL, and liquidus viscosity log₁₀η_{TL}. Table 1 and Table 2 show the results of the evaluation.

The thermal expansion coefficient α refers to a value measured with a dilatometer, and refers to an average value in the range of 30 to 380° C. Note that a cylindrical sample having a diameter of 5.0 mm and a length of 20 mm was used as a measurement sample.

The density d refers to a value measured by a well-known Archimedes method.

The water content in glass is a value measured by the single-band method described above.

The strain point Ps and the annealing temperature Ta are values measured on the basis of ASTM C336.

The softening temperature Ts is a value measured on the basis of ASTM C338.

The temperature at 10⁴ dPa·s, the temperature at 10³ dPa·s, and the temperature at 10^{2.5} dPa·s are values measured by a platinum sphere pull up method. Note that the temperature at 10⁴ dPa·s corresponds to a formation temperature.

The liquidus temperature TL refers to a value obtained by measuring a temperature at which crystals of glass are deposited after glass powder that passed through a standard 30-mesh sieve (500 μm) and remained on a 50-mesh sieve (300 μm) is placed in a platinum boat and then the platinum boat is kept for 24 hours in a gradient heating furnace. Note that, as the liquidus temperature TL is lower, the devitrification resistance improves, and hence devitrified crystals are difficult to precipitate in glass at the time of the forming thereof. As a result, large glass substrates can be easily manufactured at low cost.

The liquidus viscosity log₁₀η_{TL} refers to a value obtained by measuring the viscosity of glass at the liquidus temperature TL by a platinum sphere pull up method. Note that, as the liquidus viscosity log₁₀η_{TL} is higher, the devitrification resistance improves, and hence devitrified crystals are difficult to precipitate in glass at the time of the forming thereof. As a result, large glass substrates can be easily manufactured at low cost.

As evident from Table 1 and Table 2, each of Sample Nos. 1 to 16 had a water content in glass of 24.9 mmol/L or less, thus having a strain point Ps of 575° C. or more even though comprising 4.0 mass % or more of Na₂O. Note that Na₂O is a component that is useful for improving the photoelectric conversion efficiency of a CIGS-based solar cell but has a large effect of reducing the strain point Ps. Further, each of Sample Nos. 1 to 16 has a thermal expansion coefficient α of 81×10⁻⁷ to 86×10⁻⁷/° C., and hence the thermal expansion coefficient matches those of an electrode film and photoelectric conversion film in a thin-film solar cell. In addition, each of Sample Nos. 1 to 16 has a temperature at 10⁴ dPa·s of 1,175° C. or less and a liquidus viscosity log₁₀η_{TL} of 10^{4.0} dPa·s or more, and hence each of the samples is excellent in productivity.

On the other hand, Sample No. 17 had a water content in glass of 37.8 mmol/L, thus having a strain point Ps of 558° C. Thus, Sample No. 17 is probably unsuitable as a glass substrate for a thin-film solar cell.

1. A glass substrate for a solar cell, comprising as a glass composition, in terms of mass %, 40 to 70% of SiO₂, 1 to 20% of Al₂O₃, and 1 to 20% of Na₂O, and having a water content is glass of less than 25 mmol/L.

2. The glass substrate for a solar cell according to claim 1, comprising as a glass composition, in terms of mass %, 40 to 70% of SiO₂, 3 to 20% of Al₂O₃, 0 to 15% of B₂O₃, 0 to 10% of Li₂O, 1 to 20% of Na₂O, 0 to 15% of K₂O, 5 to 35% of MgO+CaO+SrO+BaO, and 0 to 10% of ZrO₂, and having a water content in glass of less than 25 mmol/L.

3. The glass substrate for a solar cell according to claim 1, wherein the glass substrate for a solar cell has a strain point of 560° C. or more.

4. The glass substrate for a solar cell according to claim 1, wherein the glass substrate for a solar cell has a thermal expansion coefficient at 30 to 380° C. of 70×10⁻⁷ to 100×10⁻⁷/° C.

5. The glass substrate for a solar cell according to claim 1, wherein the glass substrate for a solar cell is used in a thin-film solar cell.

6. The glass substrate for a solar cell according to claim 1, wherein the glass substrate for a solar cell is used in a dye-sensitized solar cell.

7. The glass substrate for a solar cell according to claim 2, wherein the glass substrate for a solar cell has a strain point of 560° C. or more.

8. The glass substrate for a solar cell according to claim 2, wherein the glass substrate for a solar cell has a thermal expansion coefficient at 30 to 380° C. of 70×10⁻⁷ to 100×10⁻⁷/° C.

9. The glass substrate for a solar cell according to claim 2, wherein the glass substrate for a solar cell is used in a thin-film solar cell.

10. The glass substrate for a solar cell according to claim 2, wherein the glass substrate for a solar cell is used in a dye-sensitized solar cell.
